(19) United States
(12) Patent Application Publication
(10) Pub. No.: US 2017/0306522 A1
(43) Pub. Date: Oct. 26, 2017

(54) APPARATUS FOR PRODUCING SiC SINGLE CRYSTAL BY SOLUTION GROWTH PROCESS AND CRUCIBLE EMPLOYED THEREIN

(71) Applicants: NIPPON STEEL & SUMITOMO METAL CORPORATION, Tokyo (JP); TOYOTA JIDOSHA KABUSHIKI KAISHA, Aichi (JP)

(72) Inventors: Kazuhito KAMEI, Kitakyushu-shi, Fukuoka (JP); Yutaka KISHIDA, Chiba-shi, Chiba (JP); Kazuhiko KUSUNOKI, Nishinomiya-shi, Hyogo (JP); Hironori DAIKOKU, Susono-shi, Shizuoka (JP); Masayoshi DOI, Nagoya-shi, Aichi (JP)

(73) Assignees: NIPPON STEEL & SUMITOMO METAL CORPORATION, Tokyo (JP); TOYOTA JIDOSHA KABUSHIKI KAISHA, Aichi (JP)

(21) Appl. No.: 15/517,210

(22) PCT Filed: Oct. 13, 2015
(86) PCT No.: PCT/JP2015/005177

§ 371 Date: Apr. 6, 2017

(30) Foreign Application Priority Data
Oct. 17, 2014 (JP) 2014-213233

(51) Int. Cl. C30B 19/06; C30B 19/08; C30B 19/04; C30B 29/36; C30B 17/00

(52) U.S. Cl. CPC C30B 19/062; C30B 29/36; C30B 17/00; C30B 19/04; C30B 19/08

(57) ABSTRACT

An object of the present invention is to provide a SIC single crystal production apparatus that stirs and heats a Si—C solution easily. The apparatus includes a crucible capable of containing a Si—C solution, a seed shaft, and an induction heater. The crucible includes a tubular portion and a bottom portion. The tubular portion includes an outer peripheral surface and an inner peripheral surface. The bottom portion is disposed at a lower end of the tubular portion. The bottom portion defines an inner bottom surface of the crucible. The outer peripheral surface includes a groove extending in a direction crossing the circumferential direction of the tubular portion.

### TECHNICAL FIELD

The present invention relates to a single crystal production apparatus and a crucible employed therein. In particular, it relates to an apparatus for producing a SiC single crystal by a solution growth process and a crucible employed therein.

### BACKGROUND ART

A solution growth process is an example of a method for producing a SiC single crystal. In the solution growth process, a seed crystal attached to the bottom edge of a seed shaft is brought into contact with a Si—C solution contained in a crucible. The portion of the Si—C solution in vicinity to the seed crystal is supercooled, whereby a SiC single crystal grows on the seed crystal.

The Si—C solution is a solution in which carbon (C) is dissolved in a melt of Si or a Si alloy. An example of a way of forming the Si—C solution is heating a graphite crucible containing Si by an induction heater. For example, a high-frequency coil is used as the induction heater. The crystal growth surface of the seed crystal attached to the seed shaft is brought into contact with the formed Si—C solution, whereby a SiC single crystal is grown.

It is preferred that the Si—C solution is stirred during the crystal growth so that the composition of the solution and the temperature distribution of the solution can be kept homogeneous. The heating by a high-frequency coil provides Lorentz force to the Si—C solution. Thereby, the Si—C solution is caused to flow and is stirred.

However, if the Si—C solution is not stirred adequately, it is hard to keep the composition of the solution and the temperature distribution of the solution homogeneous. In this case, SiC polycrystals are likely to be generated. If the SiC polycrystals stick to the crystal growth surface of the SiC single crystal, it will hinder the growth of the SiC single crystal.

Japanese Patent Application Publication No. 2005-179080 (Patent Literature 1) discloses a production method and a production apparatus that inhibit generation of polycrystals.

In the production method and the production apparatus disclosed in Patent Literature 1, a crucible containing a material solution is heated by a normal conductive coil. Patent Literature 1 teaches the following. The normal conductive coil provides Lorentz force to the melt. The Lorentz force makes the melt bulge like a dome. Consequently, it is possible to produce a SiC single bulk crystal stably without causing growth of polycrystals and without increasing the number of crystal defects.

### CITATION LIST

### Patent Literature

Patent Literature 1: Japanese Patent Application Publication No. 2005-179080

### SUMMARY OF INVENTION

### Technical Problem

The production method and the production apparatus disclosed in

Patent Literature 1, however, need an additional copper side wall having a slit because the melt bulges like a dome.

Recently, since SiC single crystals are usable for various purposes, large diameter SiC crystals are subjected to increasing demand. For production of a large diameter SiC crystal, a crucible with a larger diameter is required. In a case where a high-frequency coil is used as the induction heater, the high-frequency coil is typically disposed around the crucible. Accordingly, if the diameter of the crucible is increased, it is necessary to increase the diameter of the high-frequency coil.

The heating by an induction heater generates a magnetic flux inside the crucible. The magnetic flux generates Lorentz force and Joule heat in the Si—C solution by electromagnetic induction. The Lorentz force stirs the Si—C solution. The Joule heat heats the Si—C solution. The magnitudes of the Lorentz force and the Joule heat depend on the strength of the magnetic flux penetrating to the inside of the crucible. With regard to a high-frequency coil, as the diameter thereof is increasing, the magnetic flux in the center thereof becomes weaker. Accordingly, the stirring and the heating of the Si—C solution are likely to be inadequate. Inadequate stirring and heating of the Si—C solution cause generation of polycrystals, thereby hindering the growth of the SiC single crystal.

An object of the present invention is to provide a SiC single crystal production apparatus capable of easily stirring and heating a Si—C solution.

### Solution to Problem

A SiC single crystal production apparatus according to an embodiment of the present invention comprises a crucible capable of containing a Si—C solution, a seed shaft, and an induction heater. The crucible is capable of containing a Si—C solution. The crucible includes a tubular portion and a bottom portion. The tubular portion includes a first outer peripheral surface and an inner peripheral surface. The bottom portion is disposed at a lower end of the tubular portion. The bottom portion defines an inner bottom surface of the crucible. The seed shaft includes a bottom edge which a seed crystal is attachable to. The induction heater is disposed around the tubular portion of the crucible. The induction heater heats the crucible and the Si—C solution. The first outer peripheral surface includes a first groove extending in a direction crossing a circumferential direction of the tubular portion.

### Advantageous Effects of Invention

The SIC single crystal production apparatus according to the present invention is capable of easily stirring and heating a Si—C solution.

### BRIEF DESCRIPTION OF DRAWINGS

FIG. 1 is a schematic configuration diagram of a SiC single crystal production apparatus according to an embodiment.

FIG. 2 is a perspective view of a crucible shown in FIG. 1.

FIG. 3 is a vertical sectional view of the crucible shown in FIG. 1.

FIG. 4 is a horizontal sectional view of the crucible according to the embodiment.

FIG. 5 is a vertical sectional view of a crucible according to a second embodiment.

FIG. 6 is a temperature distribution chart (of the crucible according to the second embodiment) obtained from a thermal flow analysis.

FIG. 7 is a chart showing the temperature distribution in the radial direction obtained from the thermal flow analysis.

FIG. 8 is a chart showing the temperature distribution in the vertical direction obtained from the thermal flow analysis.

FIG. 9 is a chart showing the velocity distribution in the radial direction obtained from the thermal flow analysis.

FIG. 10 is a chart showing the velocity distribution in the vertical direction obtained from the thermal flow analysis.

FIG. 11 is an enlarged photograph of a SiC single crystal produced by use of a crucible E1.

FIG. 12 is an enlarged photograph of a SiC single crystal produced by use of a crucible E2.

### DESCRIPTION OF EMBODIMENTS

A SiC single crystal production apparatus according to an embodiment of the present invention comprises a crucible capable of containing a Si—C solution, a seed shaft, and an induction heater. The crucible is capable of containing a Si—C solution. The crucible includes a tubular portion and a bottom portion. The tubular portion includes a first outer peripheral surface and an inner peripheral surface. The bottom portion is located at the lower end of the tubular portion. The bottom portion defines an inner bottom surface of the crucible. The seed shaft includes a bottom edge which a seed crystal is attachable to. The induction heater is disposed around the tubular portion of the crucible. The induction heater heats the crucible and the Si—C solution. The first outer peripheral surface includes a first groove extending in a direction crossing a circumferential direction of the tubular portion.

Thus, according to the embodiment, the crucible used for production of a SiC single crystal includes a first groove in the first outer peripheral surface of the tubular portion. The first groove extends in a direction crossing the circumferential direction of the tubular portion. In this case, the magnetic flux generated by the induction heater and directed in the axial direction of the induction heater easily penetrates to the inside of the crucible. This promotes stirring and heating of the Si—C solution.

It is preferred that the first groove extends in the axial direction of the tubular portion.

In this case, the current induced in the wall of the crucible by the magnetic flux does not cross the first groove. Therefore, the induced current flows deep in the wall of the crucible, and the magnetic flux penetrates more deeply into the inside of the crucible.

It is preferred that the lower end of the first groove is to be located below the liquid surface of the Si—C solution.

In this case, from a lateral view, the first groove partly overlaps the Si—C solution in the crucible. Therefore, the magnetic flux penetrates directly into the Si—C solution. Accordingly, the Si—C solution receives Lorentz force more easily, and stirring of the Si—C solution is promoted. Also, the current induced by the high-frequency coil becomes greater, and heating of the Si—C solution is promoted.

It is preferred that the groove in the outer peripheral surface of the tubular portion is to extend, from a lateral view, at least from the inner bottom surface to the liquid surface of the Si—C solution.

In this case, stirring and heating of the Si—C solution is further promoted.

The bottom surface of the crucible preferably includes a second outer peripheral surface and an outer bottom surface. The second outer peripheral surface links with the first outer peripheral surface of the tubular portion. The outer bottom surface is located at the lower end of the second outer peripheral surface. The inner bottom surface is concave. The second peripheral surface has a second groove. The second groove extends in a direction crossing the circumferential direction of the tubular portion, and the second groove increases in depth as it comes closer to the outer bottom surface.

In this case, the second groove extends almost to the inner bottom surface. This promotes stirring and heating of the portion of the Si—C solution near the concave inner bottom surface.

The crucible according to the present embodiment is employed in the above-described apparatus for producing a SiC single crystal.

A SiC single crystal production method according to an embodiment of the present invention comprises: a preparation step of preparing the above-described production apparatus; a formation step of heating and melting the material for Si—C solution in the crucible by the induction heater to form a Si—C solution; and a growth step of bringing the seed crystal into contact with the Si—C solution and growing a SiC single crystal on the seed crystal while heating and stirring the Si—C solution.

The SiC single crystal production apparatus according to the present embodiment and the crucible employed in the production apparatus will hereinafter be described.

As described above, when the magnetic flux generated by the high-frequency coil penetrates more deeply into the inside of the crucible, the Si—C solution is stirred and heated more. During a crystal growth, stirring and heating of the Si—C solution inhibits generation of SiC polycrystals. This will be described below.

When the composition of the Si—C solution during a crystal growth is homogeneous, it is easy to inhibit generation of SiC polycrystals. In order to make the composition and the temperature of the Si—C solution homogeneous, it is necessary to stir and heat the Si—C solution. Also, during production of a SiC single crystal by the solution growth process, it is important to supply carbon in the Si—C solution to the crystal growth surface of the SiC single crystal. Supplying carbon to the crystal growth surface of the SiC single crystal during a crystal growth promotes the growth of the SiC single crystal. Therefore, also from the viewpoint of the crystal growth speed of the SiC single crystal, it is necessary to stir the Si—C solution.

An example of a way of stirring the Si—C solution is electromagnetic stirring by use of a high-frequency coil. An alternating current flow along the high-frequency coil generates a magnetic flux inside the high-frequency coil. Because of the alternating current flow, the direction and the strength of the magnetic flux change, and the Si—C solution receives Lorentz force. The Si—C solution in the crucible is caused to flow by the Lorentz force, and is stirred. Accordingly, when the magnetic flux penetrates more deeply into the inside of the crucible, the Si—C solution receives greater Lorentz force, and the Si—C solution is stirred more.

The magnetic flux generates an induced current in the crucible and the Si—C solution. Thereby, Joule heat is generated in the crucible and the Si—C solution. Accordingly, when the magnetic flux penetrates more deeply into the inside of the crucible, greater Joule heat is generated in the Si—C solution, and the crucible and the Si—C solution are heated more.

The strength of magnetic flux in the center of the high-frequency coil is inversely proportional to the radius of the coil. In other words, the greater the radius of the coil, the weaker magnetic flux is generated in the coil. The weaker the magnetic flux, the weaker the Lorentz force, and the less the Joule heat.

As described above, in order to stir and heat the Si—C solution in the crucible, it is necessary to make the magnetic flux penetrate deeply into the inside of the crucible. However, the tubular portion of the crucible is thick, and the thickness hinders penetration of the magnetic flux. Therefore, it is difficult to stir and heat the Si—C solution in the crucible.

According to the present embodiment, in the outer surface of the tubular portion of the crucible used for production of a SiC single crystal, a groove extending in a direction crossing the circumferential direction of the tubular portion is made. The thickness of the tubular portion in the area where the groove is made is reduced. Accordingly, the magnetic flux generated by the high-frequency coil easily penetrates to the inside of the crucible, and the Si—C solution is stirred and heated easily.

Some embodiments of the present invention will hereinafter be described with reference to the drawings. In the drawings, the same parts or the counterparts are provided with the same reference symbols, and descriptions of these parts will not be repeated.

### [Production Apparatus]

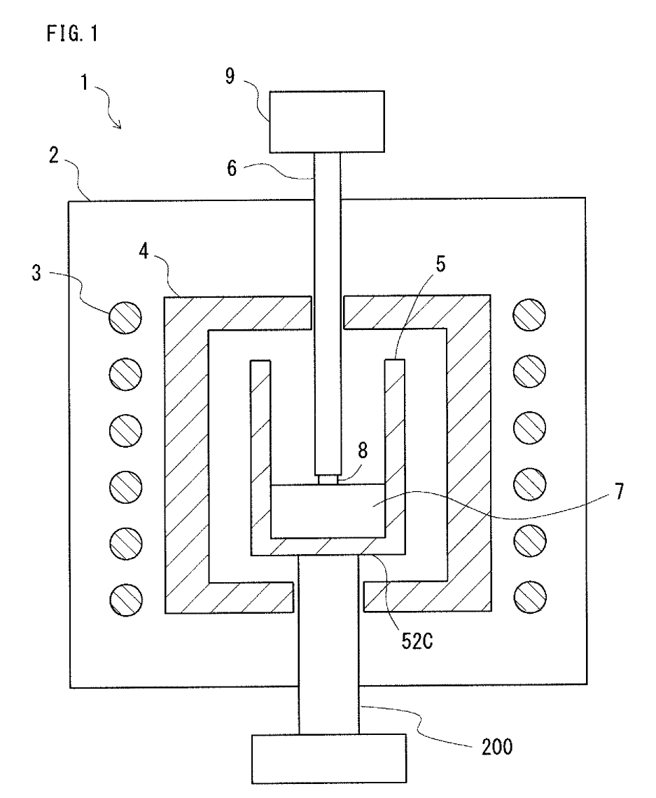

FIG. 1 is an overall view of a SiC single crystal production apparatus according to an embodiment. The production apparatus 1 illustrated in FIG. 1 is used to produce a SiC single crystal by the solution growth process. The production apparatus 1 comprises a chamber 2, an induction heater 3, a heat insulator 4, a crucible 5, a seed shaft 6, a drive unit 9, and a rotation device 200.

The chamber 2 houses the induction heater 3, the heat insulator 4 and the crucible 5. When a SiC single crystal is produced, the chamber 2 is cooled.

The heat insulator 4 is like a housing. The heat insulator 4 houses the crucible 5 and keeps the crucible 5 warm. The heat insulator 4 has a top lid and a bottom lid, each of which has a through hole in the center. The seed shaft 6 is inserted through the through hole made in the top lid. The rotation device 200 is inserted through the through hole made in the bottom lid.

The seed shaft 6 extends downward from above the chamber 2. The top edge of the seed shaft 6 is attached to the drive unit 9. The seed shaft 6 pierces into the chamber 2 and the heat insulator 4. During a crystal growth, the bottom edge of the seed shaft 6 is located inside the crucible 5. A seed crystal 8 is attachable to the bottom edge of the seed shaft 6, and when a SiC single crystal is produced, a seed crystal 8 is attached to the bottom edge. The seed crystal is preferably a SiC single crystal. The seed shaft 6 is movable up and down by the drive unit 9. The seed shaft 6 is also rotatable around the axis by the drive unit 9.

The rotation device 200 is attached to the outer bottom surface 52C of the crucible 5. The rotation device 200 pierces through the lower side of the heat insulator 4 and the lower side of the chamber 2. The rotation device 2 is capable of rotating the crucible 5 around the central axis of the crucible 5. The rotation device 200 is also capable of lifting and lowering the crucible 5.

The induction heater 3 is disposed around the crucible 5, and more specifically, is disposed around the heat insulator 4. The induction heater 3 is, for example, a high-frequency coil. In this case, the axis of the high-frequency coil is directed in the vertical direction of the production apparatus 1. It is preferred that the high-frequency coil is arranged coaxially with the seed shaft 6.

The crucible 5 contains a Si—C solution 7. The material of the crucible 5 preferably contains carbon. In this case, the crucible 5 serves as a supply source of carbon to the Si—C solution 7. The crucible 5 is made of, for example, graphite. The crucible 5 is heated by the induction heater 3. Accordingly, the crucible 5 serves as a heat source to heat the Si—C solution 7 during formation of the Si—C solution and growth of the SiC single crystal.

The Si—C solution 7 is the material of the SiC single crystal, and contains silicon (Si) and carbon (C). Si—C solution 7 may contain not only Si and C but also other metal elements. The Si—C solution 7 is produced by dissolving carbon (C) in a melt of Si or a mixture of Si and other metal elements (a Si alloy).

When a SiC single crystal is produced, the seed shaft 6 is lowered to bring the seed crystal 8 into contact with the Si—C solution 7. At the moment, the crucible 5 and the surround are kept at a crystal growth temperature. The crystal growth temperature depends on the composition of the Si—C solution. The crystal growth temperature is typically 1600 to 2000° C. The SiC single crystal is grown while the Si—C solution is maintained at the crystal growth temperature.

### First Embodiment

### [Configuration of Crucible 5]

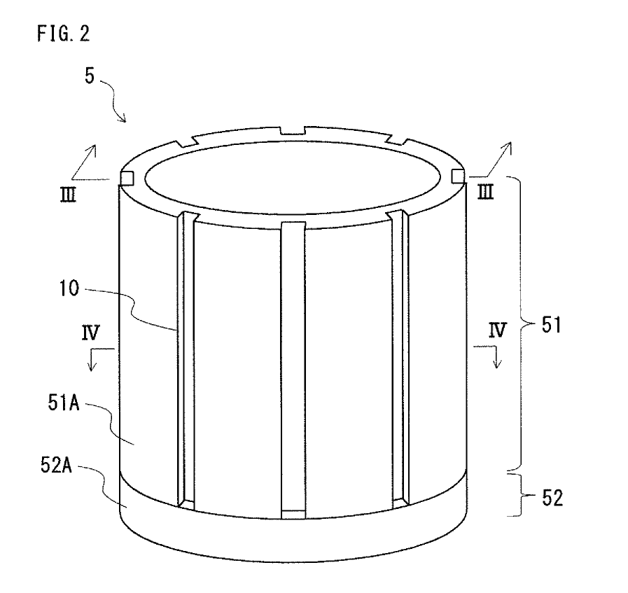

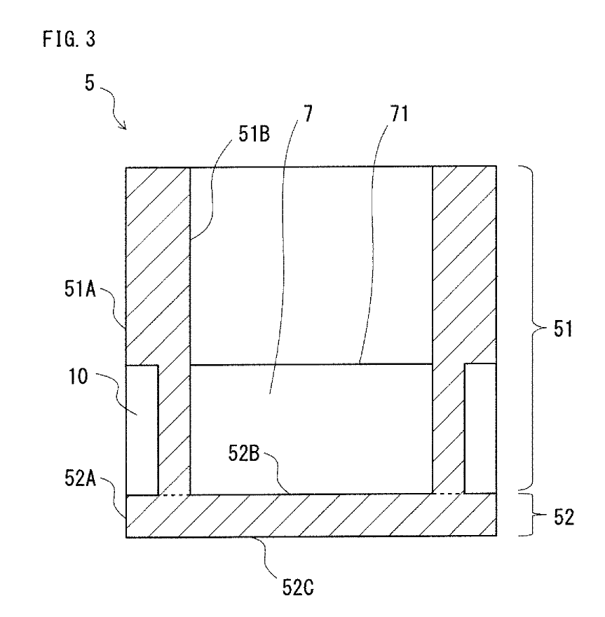

FIG. 2 is a perspective view of the crucible 5 shown in FIG. 1. FIG. 3 is a sectional view of the crucible 5 shown in FIG. 2 along the line As seen in FIGS. 2 and 3, the crucible 5 includes a tubular portion 51 and a bottom portion 52. The tubular portion 51 is tubular. For example, the tubular portion 51 is cylindrical. The tubular portion 51 includes an outer peripheral surface 51A and an inner peripheral surface 51B. The inner diameter of the tubular portion 51 is sufficiently greater than the outer diameter of the seed shaft 6. The bottom portion 52 includes an outer peripheral surface 52A, an inner bottom surface 52B and an outer bottom surface 52C. The outer peripheral surface 52A smoothly links with the outer peripheral surface 51A. The inner bottom surface 52B smoothly links with the inner peripheral surface 51B. The outer bottom surface 52C is opposed to the inner bottom surface 52B.

FIGS. 2 and 3 show a case where the bottom portion 52 is shaped like a disk. The tubular portion 51 and the bottom portion 52 may be integrally molded or may be separate components.

The outer peripheral surface 51A of the tubular portion 51 has a plurality of grooves 10. The grooves 10 extend in a direction crossing the circumferential direction of the tubular portion 51. In the case shown in FIGS. 2 and 3, the grooves 10 extend perpendicularly to the circumferential direction of the tubular portion 51 (that is, extend in the vertical direction of the crucible 5).

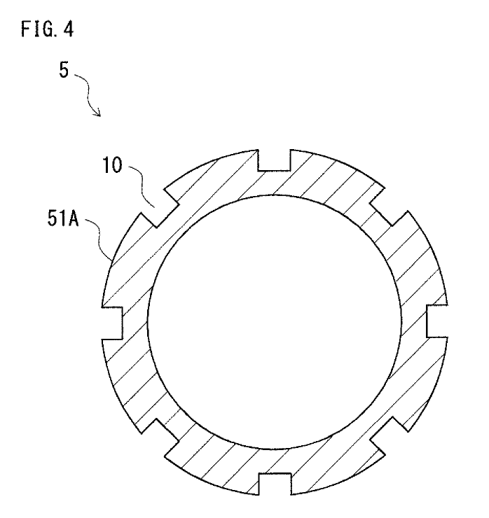

FIG. 4 is a sectional view of the crucible 5 shown in FIG. 2 along the line IV-IV. As seen in FIG. 4, the grooves 10 are arranged in the circumferential direction of the outer peripheral surface 51A. FIG. 4 shows a case where the grooves 10 are arranged at uniform intervals.

In the tubular portion 51, as described above, the portions where the grooves 10 are made are thinner than the portions where the grooves 10 are not made. Therefore, as compared with a case where no such grooves as the grooves 10 are made, an induced current flows deep in the wall of the crucible, and the magnetic flux generated by the high-frequency coil penetrates to the inside of the crucible easily. Accordingly, Si—C solution is likely to be stirred.

The direction of the magnetic flux generated by the high-frequency coil is the same as the axial direction of the coil. Accordingly, the direction of the magnetic flux is perpendicular to the circumferential direction of the tubular portion 51. Therefore, when the grooves 10 extend in a direction crossing the circumferential direction of the tubular portion 51, the magnetic flux crosses the grooves 10. Thus, in this case, the magnetic flux partly penetrates to the inside of the crucible through the thin portions of the tubular portion 51, and therefore, the magnetic flux penetrates to the inside of the crucible easily. Further, when the grooves 10 extend in the axial direction of the tubular portion 51 (that is, extend perpendicularly to the circumferential direction of the tubular portion 51) as shown in FIG. 2, the magnetic flux penetrates to the inside of the crucible without crossing the grooves 10. In this case, the magnetic flux does not pass through the thick portions of the tubular portion 51, and the magnetic flux penetrates to the inside of the crucible still easier.

When the magnetic flux penetrates to the inside of the crucible easily, the induced current generated in the Si—C solution 7 around the center of the crucible is great as compared with a case where no such grooves as the grooves 10 are made. Accordingly, the Joule heat generated in the Si—C solution 7 is great, which promotes heating of the Si—C solution 7.

The lower limit of the depth of the grooves 10 is preferably 10% of the thickness of the tubular portion 51. The upper limit of the depth of the grooves 10 is preferably 90% of the thickness of the tubular portion 51. More desirably, the lower limit of the depth of the grooves 10 is 30% of the thickness of the tubular portion 51, and the upper limit of the depth of the grooves 10 is 70% of the thickness of the tubular portion 51. The cross-sectional shape of each of the grooves 10 need not be rectangular, and may be semicircular, semi-elliptical or the like. The cross-sectional shape of the grooves 10 is not particularly limited as long as it helps partial thickness reduction of the tubular portion 51 and magnetic flux penetration to the inside of the crucible. In the case of FIG. 4, eight grooves 10 are made in the outer peripheral surface 51A. However, there is no particular limit to the number of the grooves 10. Even making only one groove 10 in the outer peripheral surface 51A promises a certain level of effect. The number of the grooves 10 may be two or more.

Preferably, the grooves 10 are circumferentially arranged along the outer peripheral surface 51 at uniform intervals as shown in FIG. 4. In this case, the magnetic flux penetrates evenly with respect to the circumferential direction, and the Si—C solution 7 is likely to be stirred and heated evenly with respect to the circumferential direction.

As seen in FIGS. 2 and 3, the lower ends of the grooves 10 are to be located below the liquid surface 71 of the Si—C solution 7. More specifically, as shown in FIG. 3, the grooves 10 are to extend, from a lateral view, at least from the inner bottom surface 52B to the liquid surface 71 of the Si—C solution 7.

In this case, from a lateral view, the grooves 10 overlap the Si—C solution 7. Therefore, the magnetic flux is likely to penetrate into the Si—C solution directly, which further promotes stirring and heating of the Si—C solution 7.

FIG. 4 shows that the grooves 10 extend from the inner bottom surface 52B to the liquid surface 71. However, the grooves 10 need not extend from the inner bottom surface 52B to the liquid surface 71. Even if the grooves 10 do not overlap the Si—C solution 7 from a lateral view, the magnetic flux penetrates into the Si—C solution 7 to some extent. However, when the lower ends of the grooves 10 are below the liquid surface 71, and the grooves 10 at least partly overlap the Si—C solution 7, the magnetic flux penetrates into the Si—C solution 7 more easily.

### Second Embodiment

### [Configuration of Crucible 50]

The inner bottom surface of the crucible may be concave. When the inner bottom surface is concave, it is preferred that the portion of the Si—C solution 7 near the inner bottom surface is stirred more.

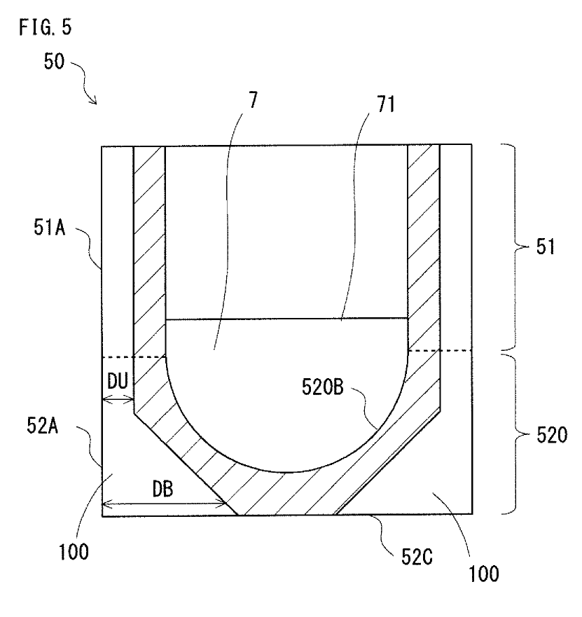

FIG. 5 is a longitudinal sectional view of a crucible 50 employed in a SiC single crystal production apparatus according to a second embodiment. As illustrated in FIG. 5, the crucible 50 includes a tubular portion 51 and a bottom portion 520. The tubular portion 51 of the crucible 50 is the same as the tubular portion 51 of the crucible 5 illustrated in FIGS. 2 and 3.

The bottom portion 520 includes not a flat inner bottom surface as the inner bottom surface 52B of the bottom portion 52 but a concave inner bottom surface 520B. As shown in FIG. 5, the longitudinal section of the inner bottom surface 520B is shaped like a bow and is concave.

In order to stir the Si—C solution 7 filled in the space defined by the concave inner bottom surface 520B, it is preferred that grooves extending almost to the inner bottom surface 520B are made. Therefore, the outer peripheral surface 52A of the bottom portion 520 has grooves 100. The grooves 100, as with the grooves 10, extend in a direction crossing the circumference direction of the tubular potion 51. The grooves 100 also increase in depth as they come from the upper part of the bottom portion 520 toward the outer bottom surface 52C. Specifically, the depth DB of the lower parts (near the outer bottom surface 52C) of the grooves 100 is greater than the depth DU of the upper parts of the grooves 100.

In this case, the grooves 100 are made to extend almost to the concave inner bottom surface 520B. Accordingly, the magnetic flux penetrates into the Si—C solution 7 filled in the space defined by the concave inner bottom surface 520B, which promotes stirring and heating of the Si—C solution 7.

As is the case with the first embodiment, when the grooves 100 extend in the axial direction of the tubular portion 51 (extend perpendicularly to the circumferential direction of the tubular portion 51), the magnetic flux penetrates more deeply into the inside of the crucible 50.

### [Production Method]

A production method according to an embodiment of the present invention comprises a preparation step, a formation step, and a growth step. In the preparation step, the production apparatus 1 is prepared, and a seed crystal 8 is attached to the seed shaft 6. In the formation step, a Si—C solution 7 is produced by the induction heater 3. In the growth step, the seed crystal 8 is brought into contact with the Si—C solution 7, whereby a SiC single crystal is grown. These steps will hereinafter be described.

### [Preparation Step]

With reference to FIG. 1, the above-described production apparatus 1 is prepared in the preparation step. Subsequently, a seed crystal 8 is attached to the bottom edge of the seed shaft 6.

### [Formation Step]

In the formation step, the material for Si—C solution 7 in the crucible 5 is heated, whereby a Si—C solution 7 is produced. The crucible 5 is placed on the rotation device 200 in the chamber 2. The crucible 5 contains material for Si—C solution 7. It is preferred that the crucible 5 and the rotation device 200 are coaxially arranged. The heat insulator 4 is disposed around the crucible 5. The induction heater 3 is disposed around the heat insulator 4.

Next, the chamber 2 is filled with an inert gas. The inert gas is, for example, helium, argon or the like. The pressure inside the chamber 2 is preferably the atmospheric pressure. If the pressure inside the chamber 2 is below the atmospheric pressure (reduced pressure) or if the inside of the chamber 2 is vacuum, the Si—C solution 7 in the crucible 5 vapors easily. Vaporization of the Si—C solution 7 leads to a great change in the level of the liquid surface of the Si—C solution 7, thereby resulting in an instable growth of the SiC single crystal. The induction heater 3 heats the crucible 5 and the material for Si—C solution 7 in the crucible 5. The material for Si—C solution is, for example, Si or a mixture of Si and other metal elements (a Si alloy). The heated material for Si—C solution 7 melts. For example, when the crucible 5 is graphite, carbon is dissolved out from the graphite crucible 5, whereby a Si—C solution 7 is produced.

### [Growth Step]

After the production of the Si—C solution 7, the seed crystal 8 is dipped in the Si—C solution 7. Specifically, the seed shaft 6 is lowered to bring the seed crystal 8 attached to the bottom edge of the seed shaft 6 into contact with the Si—C solution 7. After the seed crystal 8 comes into contact with the Si—C solution 7, the induction heater 3 heats the crucible 5 and the Si—C solution 7 to maintain the crucible 5 and the Si—C solution 7 at a crystal growth temperature. The crystal growth temperature depends on the composition of the Si—C solution 7. The crystal growth temperature is typically 1600 to 2000 C.

Next, the portion of the Si—C solution 7 in vicinity to the seed crystal 8 is supercooled, whereby SiC is supersaturated. In order to supercool the portion of the Si—C solution, for example, the induction heater 3 is controlled to make the temperature of the portion of the Si—C solution 7 in vicinity to the seed crystal 8 lower than the temperature of the other portion. Alternatively, the portion in vicinity to the seed crystal 8 may be cooled by a coolant. Specifically, a coolant is circulated inside the seed shaft 6. The coolant is, for example, an inert gas such as helium, argon or the like.

### EXAMPLE 1

Thermal flow of the Si—C solution in crucibles that differ from one another in the form of grooves was simulated.

### [Simulation Method]

The simulation was conducted on the assumption that a SiC single crystal production apparatus having the same structure as the production apparatus I shown in FIG. 1 was used. A thermal flow analysis was performed by use of an axially symmetric RZ coordinate system. The induction heater 3 was assumed to be a high-frequency coil. The alternating current applied to the high-frequency coil was assumed to have a frequency of 6 kHz. The alternating current was assumed to have a current value of 520 to 565 A.

In the thermal flow analysis, three crucibles (S1 to S3) that differ from one another in the form of grooves were used as computation models. The crucible S1 had no grooves. The crucible S2 had grooves in the outer peripheral surface of the tubular portion, and the grooves extended from the bottom edge to the top edge of the tubular portion as shown in FIG. 3. The grooves extended in a direction crossing the circumferential direction of the tubular portion. The grooves were eight in number, and the eight grooves were arranged at uniform intervals in the circumferential direction of the tubular portion. The crucible S3 had the same grooves as those of the crucible 50 shown in FIG. 5, and as compared with the crucible S2, the crucible S3 further had grooves in the bottom portion. The grooves of the crucible S2 and the crucible S3 had the following dimensions: a width of 6 mm, a depth of 4 mm, and a length of 155 mm. Further, with regard to the grooves of the crucible S3, the depth DB (see FIG. 5) was 30 mm.

On the above conditions, a thermal flow analysis by simulation was performed. For the simulation, a general-purpose thermal flow analysis application (made by COMSOL, tradename: COMSOL-Multiphysics) was used.

### [Simulation Results]

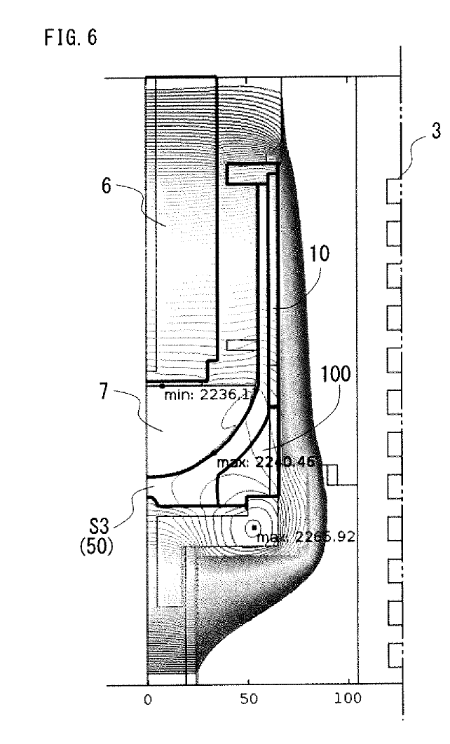

FIG. 6 shows the results of the simulation. FIG. 6 is a temperature distribution chart obtained from the simulation of thermal flow in the crucible S3. In FIG. 6, isothermal lines are indicated.

As seen in FIG. 6, the number of isothermal lines in the Si—C solution 7 is small. This means that there was little temperature variation in the portion of the inside of the crucible S3 where the Si—C solution 7 was present and that heat was averaged in the portion.

### [Heating Effect]

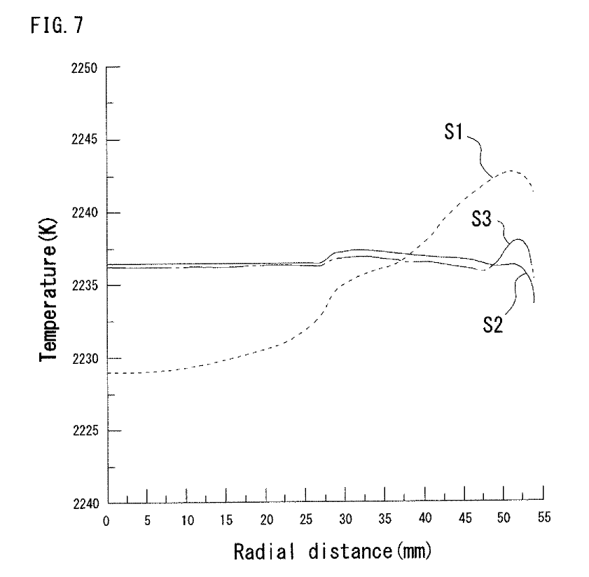

FIG. 7 is a chart showing the Si—C solution surface temperature distribution in the radial direction in each of the crucibles S1 to S3. The horizontal axis indicates the radial distance (mm) from the center of the crucible. The vertical axis indicates the surface temperature (CC) of the Si—C solution. In FIG. 7, the broken line indicates the result regarding the crucible S1. The solid line indicates the result regarding the crucible S2. The chain line indicates the result regarding the crucible S3.

As seen in FIG. 7, in each of the crucibles S2 and S3 which had grooves on the outer peripheral surface, the surface temperature of the Si—C solution was uniform in the radial direction, as compared with in the crucible S1 which had no grooves. Moreover, in each of the crucibles S2 and S3, the surface temperature of the Si—C solution in the center of the crucible was high, as compared with in the crucible Si.

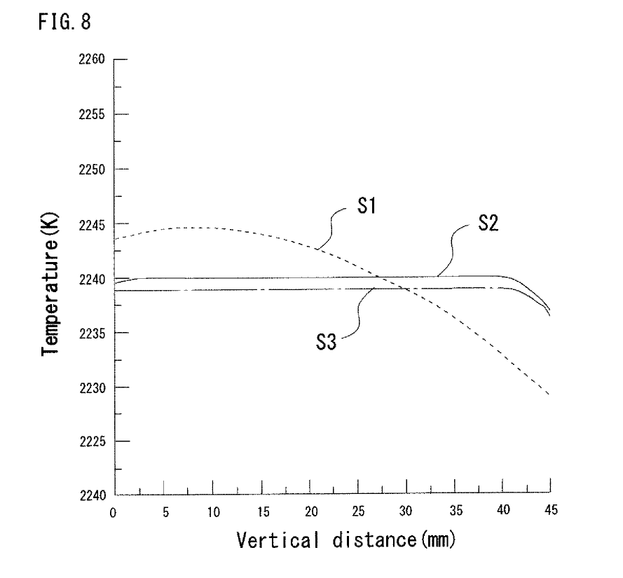

FIG. 8 is a chart showing the Si—C solution surface temperature distribution in the vertical direction along the central axis of each of the crucibles S1 to S3. The horizontal axis indicates the vertical distance from the inner bottom surface. The vertical axis indicates the temperature. In FIG. 8, the broken line indicates the result regarding the crucible S1. The solid line indicates the result regarding the crucible S2. The chain line indicates the result regarding the crucible S3.

As seen in FIG. 8, in each of the crucibles S2 and S3, the temperature of the Si—C solution was uniform also in the depth direction, as compared with in the crucible S1. In the crucible S1, the temperature of the Si—C solution was not uniform in the depth direction, and the nearer the inner bottom surface, the lower the temperature.

### [Stirring Effect]

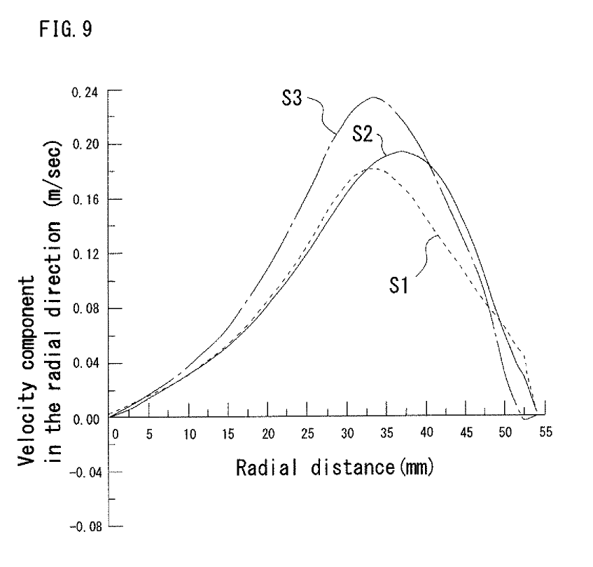

FIG. 9 is a chart showing the Si—C solution velocity distribution in the radial direction in each of the crucibles S1 to S3. The horizontal axis indicates the radial distance from the center of the crucible. The vertical axis indicates the velocity component in the radial direction. In this regard, a positive value indicates a movement in a direction from the center of the crucible to the outer peripheral surface. In FIG. 9, the broken line indicates the result regarding the crucible S1. The solid line indicates the result regarding the crucible S2. The chain line indicates the result regarding the crucible S3. As seen in FIG. 9, the velocity component in the radial direction was the greatest in the crucible S3. The second greatest was in the crucible S2, and the least was in the crucible S1.

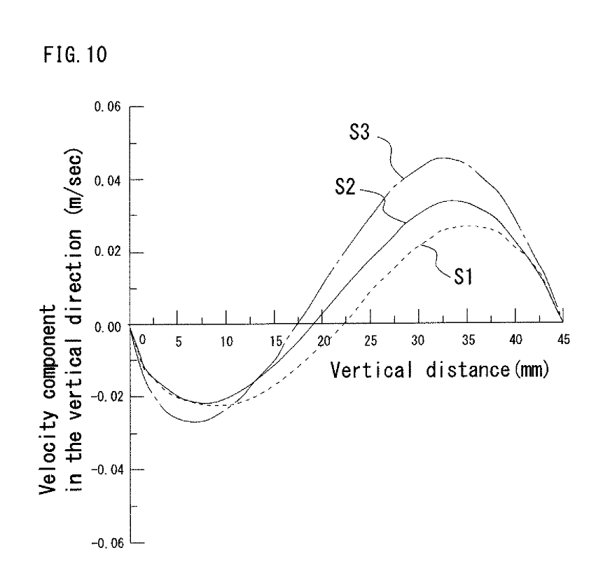

FIG. 10 is a chart showing the Si—C solution velocity distribution in the vertical direction along the central axis of each of the crucibles Si to S3. The horizontal axis indicates the vertical distance from the inner bottom surface. The vertical axis indicates the velocity component in the vertical direction. In FIG. 10, the broken line indicates the result regarding the crucible S1. The solid line indicates the result regarding the crucible S2. The chain line indicates the result regarding the crucible S3. As seen in FIG. 10, the velocity component in the vertical direction was the greatest in the crucible S3. The second greatest was in the crucible S2, and the least was in the crucible S1.

The absolute values of the maximum flow velocities of the Si—C solution in the crucibles S1 to S3 were calculated from the flow analysis results. That in the crucible S1 was 0.198 m/s, that in the crucible S2 was 0.215 m/s, and that in the crucible S3 was 0.268 m/s. These results show that the crucibles according to the embodiments provided great Lorentz force to the Si—C solution, as compare with the crucible S1 having no grooves. In other words, the crucibles according to the embodiments stirred the Si—C solution well, as compared with the crucible S1 having no grooves.

### EXAMPLE 2

In Example 2, SiC single crystals were produced by use of crucibles (E1 and E2) that differ in the form of the grooves in the outer peripheral surface. Then, the quality of the produced SiC single crystals was evaluated.

The crucible E1 was made of graphite, and was in the shape of a cylinder having an inner diameter of 110 mm and an outer diameter of 130 mm. The inner bottom surface of the crucible E1 was semispherically concave. The seed crystal used for this example was a SiC single crystal. The seed crystal attached to the seed shaft had a diameter of 2 inches. The material for Si—C solution contained Si and Cr at an atom ratio of Si:Cr=6=4. The temperature around the SiC seed crystal was 1950° C. The crystal growth time was 10 hours.

The crucible E2 was a crucible having eight grooves on the outer peripheral surface of the tubular portion of the crucible E1. The grooves extended in the axial direction of the tubular portion from the bottom edge to the top edge of the tubular portion. The grooves were arranged at uniform intervals around the axis of the tubular portion. Each of the grooves had the following dimensions: a width of 6 mm, a depth of 4 mm, and a length of 155 mm. There were no other differences in structure between the crucible E1 and the crucible E2. The conditions of SiC single crystal production were the same as the conditions of SiC single crystal production by use of the crucible E1.

### [Evaluation]

The crystal growth surface of each of the produced SiC single crystals was observed by an optical microscope.

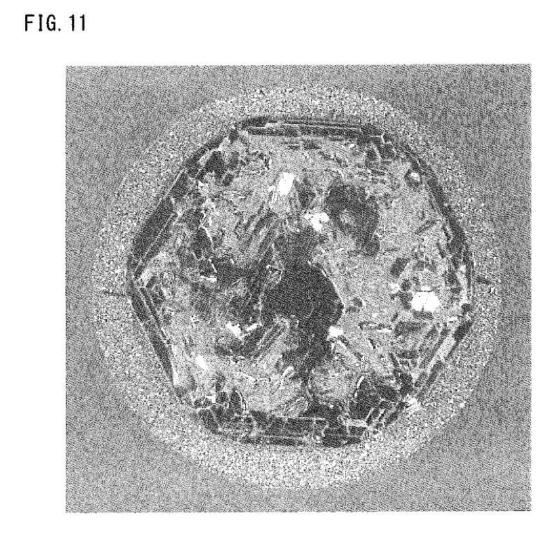

FIG. 11 is an enlarged photograph of the crystal growth surface of the SiC single crystal produced in the crucible E1. As shown in FIG. 11, sticking of many SiC polycrystals to the crystal growth surface was found.

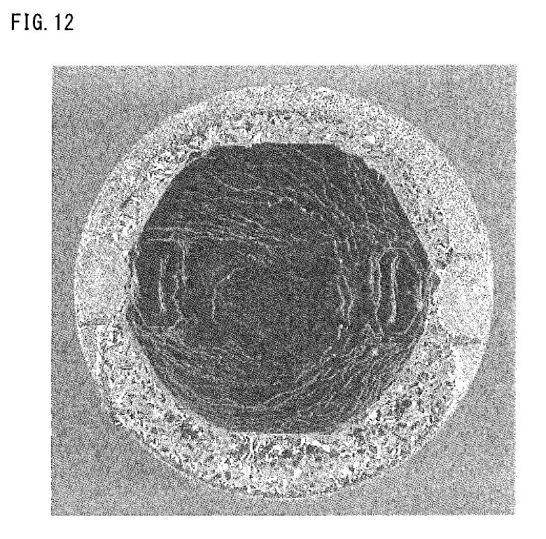

FIG. 12 is an enlarged photograph of the crystal growth surface of the SiC single crystal produced in the crucible E2. As seen in FIG. 12, sticking of SiC polycrystals to the crystal growth surface was hardly found. In the SiC single crystal production method according to the embodiment, a high-quality SiC single crystal could be produced even by use of a crucible with an inner diameter larger than ever before.

The embodiments described above are merely examples, and the present invention is not restricted to the embodiments.

LIST OF REFERENCE SYMBOLS

3: induction heater

5, 50: crucible

51: tubular portion

51A: outer peripheral surface of tubular portion

52, 520: bottom portion

52A: outer peripheral surface of bottom portion

52B, 520B: inner bottom surface of bottom portion

52C: outer bottom surface of bottom portion

7: Si—C solution

10, 100: groove

1. An apparatus for producing a SiC single crystal by a solution growth process, the apparatus comprising:
a crucible including a tubular portion including a first outer peripheral surface and an inner peripheral surface, and a bottom portion disposed at a lower end of the tubular portion and defining an inner bottom surface, the crucible capable of containing a Si—C solution;
a seed shaft including a bottom edge which a seed crystal is attachable to; and
an induction heater disposed around the tubular portion of the crucible, the induction heater configured to heat the crucible and the Si—C solution, wherein
the first outer peripheral surface includes a first groove extending in a direction crossing a circumferential direction of the tubular portion.

2. The apparatus for producing a SiC single crystal according to claim 1, wherein
the first groove extends in an axial direction of the tubular portion.

3. The apparatus for producing a SiC single crystal according to claim 1, wherein
a lower end of the first groove is to be located below a liquid surface of the Si—C solution.

4. The apparatus for producing a SiC single crystal according to claim 3, wherein
from a lateral view, the first groove is to extend at least from the inner bottom surface of the crucible to the liquid surface of the Si—C solution.

5. The apparatus for producing a SiC single crystal according to claim 1, wherein
the bottom portion includes:
a second outer peripheral surface linking with the first outer peripheral surface; and
an outer bottom surface disposed at a lower end of the second outer peripheral surface;
the inner bottom surface is concave; and
the second outer peripheral surface includes a second groove extending in a direction crossing the circumferential direction of the tubular portion and increasing in depth as the second groove comes closer to the outer bottom surface.

6. A crucible to be employed in an apparatus for producing a SiC single crystal by a solution growth process and capable of containing a Si—C solution, the crucible comprising:
a tubular portion including a first outer peripheral surface and an inner peripheral surface; and
a bottom portion disposed at a lower end of the tubular portion and defining an inner bottom surface, wherein
the tubular portion includes a first groove in the first outer peripheral surface, the groove extending in a direction crossing a circumferential surface of the tubular portion.

7. The crucible according to claim 6, wherein
the first groove extends in an axial direction of the tubular portion.

8. The crucible according to claim 6, wherein
a lower end of the first groove is to be located below a liquid surface of the Si—C solution.

9. The crucible according to claim 8, wherein
from a lateral view, the first groove is to extend at least from the inner bottom surface of the crucible to the liquid surface of the Si—C solution.

10. The crucible according to claim 6, wherein
the bottom portion includes:
a second outer peripheral surface linking with the first outer peripheral surface; and
an outer bottom surface disposed at a lower end of the second outer peripheral surface;
the inner bottom surface is concave; and
the second outer peripheral surface includes a second groove extending in a direction crossing the circumferential direction of the tubular portion and increasing in depth as the second groove comes closer to the outer bottom surface.

11. A method for producing a SiC single crystal by a solution growth process, the method comprising:
a preparation step of preparing a SiC single crystal production apparatus comprising a crucible including a tubular portion including a first outer peripheral surface and an inner peripheral surface, and a bottom portion disposed at a lower end of the tubular portion and defining an inner bottom surface, the crucible capable of containing material for Si—C solution, a seed shaft including a bottom edge which a seed crystal is attached to, and an induction heater disposed around the tubular portion of the crucible, the induction heater configured to heat the crucible and the Si—C solution, wherein the first outer peripheral surface includes a first groove extending in a direction crossing a circumferential direction of the tubular portion;
a formation step of heating and melting the material contained in the crucible to form the SiC solution; and
a growth step of bringing the seed crystal into contact with the Si—C solution and growing the SiC single crystal on the seed crystal while heating and stirring the Si—C solution by the induction heater.

12. The apparatus for producing a SiC single crystal according to claim 2, wherein
the bottom portion includes:
a second outer peripheral surface linking with the first outer peripheral surface; and
an outer bottom surface disposed at a lower end of the second outer peripheral surface;
the inner bottom surface is concave; and
the second outer peripheral surface includes a second groove extending in a direction crossing the circumferential direction of the tubular portion and increasing in depth as the second groove comes closer to the outer bottom surface.

13. The apparatus for producing a SiC single crystal according to claim 3, wherein
the bottom portion includes:
a second outer peripheral surface linking with the first outer peripheral surface; and
an outer bottom surface disposed at a lower end of the second outer peripheral surface;
the inner bottom surface is concave; and
the second outer peripheral surface includes a second groove extending in a direction crossing the circumferential direction of the tubular portion and increasing in depth as the second groove comes closer to the outer bottom surface.

14. The apparatus for producing a SiC single crystal according to claim 4, wherein
the bottom portion includes:
a second outer peripheral surface linking with the first outer peripheral surface; and
an outer bottom surface disposed at a lower end of the second outer peripheral surface;
the inner bottom surface is concave; and
the second outer peripheral surface includes a second groove extending in a direction crossing the circumferential direction of the tubular portion and increasing in depth as the second groove comes closer to the outer bottom surface.

15. The crucible according to claim 7, wherein
the bottom portion includes:
a second outer peripheral surface linking with the first outer peripheral surface; and
an outer bottom surface disposed at a lower end of the second outer peripheral surface;
the inner bottom surface is concave; and
the second outer peripheral surface includes a second groove extending in a direction crossing the circumferential direction of the tubular portion and increasing in depth as the second groove comes closer to the outer bottom surface.

16. The crucible according to claim 8, wherein
the bottom portion includes:
a second outer peripheral surface linking with the first outer peripheral surface; and
an outer bottom surface disposed at a lower end of the second outer peripheral surface;
the inner bottom surface is concave; and
the second outer peripheral surface includes a second groove extending in a direction crossing the circumferential direction of the tubular portion and increasing in depth as the second groove comes closer to the outer bottom surface.

17. The crucible according to claim 9, wherein
the bottom portion includes:
a second outer peripheral surface linking with the first outer peripheral surface; and
an outer bottom surface disposed at a lower end of the second outer peripheral surface;
the inner bottom surface is concave; and
the second outer peripheral surface includes a second groove extending in a direction crossing the circumferential direction of the tubular portion and increasing in depth as the second groove comes closer to the outer bottom surface.
